(19) United States
(12) Patent Application Publication
(10) Pub. No.: US 2026/0331200 A1
(43) Pub. Date: Oct. 22, 2026

(54) MEMORY DEVICES AND MEMORY SYSTEMS CONFIGURED TO GENERATE ONE OR MORE INTERNAL CLOCK SIGNALS

(71) Applicant: SK hynix Inc., Icheon-si Gyeonggi-do (KR)

(72) Inventors: Min Kyu MOON, Icheon-si Gyeonggi-do (KR); Young Jun PARK, Icheon-si Gyeonggi-do (KR); Su Hyun OH, Icheon-si Gyeonggi-do (KR); Kyung Jun CHO, Icheon-si Gyeonggi-do (KR)

(73) Assignee: SK hynix Inc., Icheon-si Gyeonggi-do (KR)

(21) Appl. No.: 19/298,789

(22) Filed: Aug. 13, 2025

(30) Foreign Application Priority Data
Apr. 22, 2025 (KR) 10-2025-0052682

(51) Int. Cl. G11C 29/12; G11C 29/14; G11C 29/36

(52) U.S. Cl. CPC G11C 29/12015; G11C 29/14; G11C 29/36; G11C 2029/3602

(57) ABSTRACT

A memory device includes a calibration code generation circuit configured to generate a calibration code based on a calibration test mode signal and a calibration clock signal. The memory device includes a code selection circuit configured to select one of the calibration code and a manual code as a selected calibration code based on a manual test mode signal. The memory device includes a clock activation signal calibration circuit configured to delay a latch clock activation signal based on the selected calibration code to generate a delayed clock activation signal. The memory device includes a clock calibration circuit configured to calibrate internal clock signals based on the selected calibration code and the delayed clock activation signal to generate internal calibration clock signals.

### CROSS-REFERENCE TO RELATED APPLICATIONS

The present application claims priority under 35 U.S.C § 119(a) to Korean Application No. 10-2025-0052682, filed in the Korean Intellectual Property Office on Apr. 22, 2025, the entire contents of which application is incorporated herein by reference.

### BACKGROUND

### 1. Technical Field

The present disclosure generally relates to memory devices and memory systems, and more particularly, to memory devices and memory systems configured to generate one or more internal clock signals.

### 2. Related Art

Stack memory systems such as high bandwidth memory (HBM) devices are used in a wide range of applications due to their high bandwidth and energy efficiency. Unlike conventional memory systems that use parallel data buses, stack memory systems include a stack memory device including a base chip and a plurality of memory chips interconnected by through silicon vias (TSVs). The stack memory device includes a physical interface, such as a physical layer for communication with a processor. The physical layer is designed for high-speed data transmission and efficient communication.

### SUMMARY

The present disclosure, in an embodiment, describes a memory device that may include a calibration code generation circuit configured to generate a calibration code based on a calibration test mode signal and a calibration clock signal, a code selection circuit configured to select one of the calibration code and a manual code as a selected calibration code based on a manual test mode signal, a clock activation signal calibration circuit configured to delay a latch clock activation signal based on the selected calibration code to generate a delayed clock activation signal, and a clock calibration circuit configured to calibrate internal clock signals based on the selected calibration code and the delayed clock activation signal to generate internal calibration clock signals.

The present disclosure, in an embodiment, describes a memory system that may include a base die and a plurality of core dies disposed over an interposer. The base die may include a calibration code generation circuit configured to generate a calibration code based on a calibration test mode signal and a calibration clock signal, a code selection circuit configured to select one of the calibration code and a manual code as a selected calibration code based on a manual test mode signal, a clock activation signal calibration circuit configured to delay a latch clock activation signal based on the selected calibration code to generate a delayed clock activation signal, and a clock calibration circuit configured to calibrate internal clock signals based on the selected calibration code and the delayed clock activation signal to generate internal calibration clock signals.

The present disclosure, in an embodiment, describes a memory system that may include a base die configured to control a plurality of core dies. The base die may include a physical layer configured to control transmission of data, commands, and addresses using a plurality of channels between the core dies and a processor, and a serial-to-parallel conversion circuit configured to convert serial signals transmitted serially through the physical layer into parallel signals, align the converted parallel signals through a plurality of alignment circuits, and transmit the parallel signals to a through via region. At least one of the plurality of alignment circuits may include an internal clock generation circuit configured to generate a calibration code based on a calibration test mode signal and a calibration clock signal, delays a latch clock activation signal based on the calibration code to generate a delayed clock activation signal, and calibrates internal clock signals based on the calibration code to generate internal calibration clock signals.

### BRIEF DESCRIPTION OF THE DRAWINGS

FIG. 1 illustrates an internal clock generation circuit according to an embodiment of the present disclosure.

FIG. 2 illustrates a calibration code generation circuit according to an embodiment of the present disclosure.

FIG. 3 illustrates a synthetic test strobe generation circuit according to an embodiment of the present disclosure.

FIG. 4 illustrates a strobe synthesis circuit according to an embodiment of the present disclosure.

FIG. 5 is a timing diagram during an operation of a strobe synthesis circuit according to an embodiment of the present disclosure.

FIG. 6 illustrates a strobe comparison circuit according to an embodiment of the present disclosure.

FIG. 7 is a timing diagram during an operation of a strobe comparison circuit according to an embodiment of the present disclosure.

FIG. 8 illustrates a clock activation signal calibration circuit according to an example of the present disclosure.

FIG. 9 is a table illustrating an operation of a code decoder according to an example of the present disclosure.

FIG. 10 illustrates a code delay circuit according to an embodiment of the present disclosure.

FIG. 11 is a timing diagram during operations of a clock activation signal calibration circuit and a clock calibration circuit according to an embodiment of the present disclosure.

FIG. 12 illustrates a base die circuit according to an embodiment of the present disclosure.

FIG. 13 illustrates a memory system according to an embodiment of the present disclosure.

### DETAILED DESCRIPTION

In the following description of embodiments, when a parameter is referred to as being “preset” or “predetermined,” it may be intended to mean that a value of the parameter is determined in advance when the parameter is used in a process or an algorithm. The value of the parameter may be set when the process or the algorithm starts or may be set during a period in which the process or the algorithm is executed.

Terms such as “first” and “second” are used to distinguish between various elements and do not imply size, order, priority, quantity, or importance of the elements. For example, a first element may be named as a second element in one example, and the second element may be named as a first element in another example.

When one component is identified as “connected” to another component, the components may be connected directly or through an intervening component between the components. When two components are identified as “directly connected,” one component is directly connected to the other component without an intervening component between the two components.

A logic “high” level and a logic “low” level may be used to describe logic levels of electric signals. A signal at a logic high level is distinguished from a signal at a logic low level. For example, when a signal at a first voltage corresponds to a signal at a logic high level, a signal at a second voltage corresponds to a signal at a logic low level. In an embodiment, the logic high level may be a voltage level that is higher than a voltage level of the logic low level. Logic levels of signals may be different or opposite according to the embodiments. For example, a signal at a logic high level in one embodiment may be at a logic low level in another embodiment, and a signal at a logic low level in one embodiment may be at a logic high level in another embodiment.

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

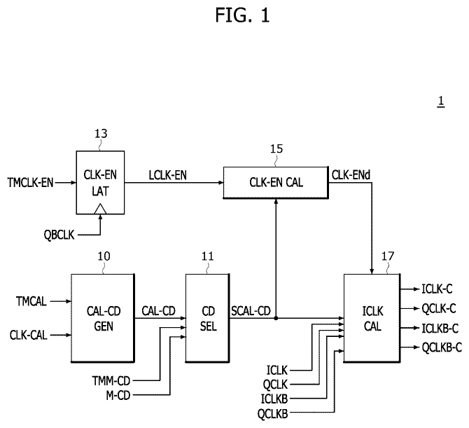

FIG. 1 illustrates an internal clock generation circuit 1 according to an embodiment of the present disclosure.

As shown in FIG. 1, the internal clock generation circuit 1 includes a calibration code generation circuit (CAL-CD GEN) 10, a code selection circuit (CD SEL) 11, a clock activation signal latch (CLK-EN LAT) 13, a clock activation signal calibration circuit (CLK-EN CAL) 15, and a clock calibration circuit (ICLK CAL) 17.

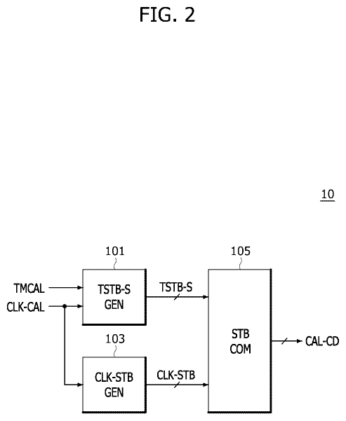

The calibration code generation circuit 10 generates a calibration code CAL-CD based on a calibration test mode signal TMCAL and a calibration clock signal CLK-CAL. The calibration code generation circuit 10 generates a synthetic test strobe, for example, a synthetic test strobe TSTB-S in FIG. 2 and a clock strobe, for example, a clock strobe CLK-STB in FIG. 2, based on the calibration test mode signal TMCAL and the calibration clock signal CLK-CAL, and compares the synthetic test strobe and the clock strobe to generate the calibration code CAL-CD. The calibration test mode signal TMCAL is a test mode signal that is activated for calibration test operation. The calibration test operation is performed to calibrate internal clocks (ICLK, QCLK, ICLKB, QCLKB). The calibration test mode signal TMCAL may be activated or not by command and address in an initialization operation of the mode register set, etc. The calibration code generation circuit 10 may generate the calibration code CAL-CD having a bit set corresponding to a delay interval difference in order to calibrate the delay interval difference between the paths through which the strobe and clock signals are transmitted.

The code selection circuit 11 is electrically connected to the calibration code generation circuit 10 and receives the calibration code CAL-CD from the calibration code generation circuit 10. The code selection circuit 11 generates a selected calibration code SCAL-CD based on the calibration code CAL-CD, a manual test mode signal TMM-CD, a manual code M-CD. The code selection circuit 11 selects and outputs the manual code M-CD as the selected calibration code SCAL-CD when the manual test mode signal TMM-CD is activated, and selects and outputs the calibration code CAL-CD as the selected calibration code SCAL-CD when the manual test mode signal TMM-CD is deactivated.

The clock activation signal latch 13 generates a latch clock activation signal LCLK-EN based on a test mode activation signal TMCLK-EN and an internal clock signal QBCLK. The clock activation signal latch 13 latch the test mode activation signal TMCLK-EN to generate the latch clock activation signal LCLK-EN based on the internal clock signal QBCLK. The test mode activation signal TMCLK-EN may be activated to perform test mode. The clock activation signal latch 13 latches the activated test mode activation signal TMCLK-EN in synchronization with a rising edge of the internal clock signal QBCLK to generate an activated latch clock activation signal LCLK-EN. The rising edge of the internal clock signal QBCLK indicates the point at which the logic level of the internal clock signal QBCLK transitions from a logic low level to a logic high level. The internal clock signal QBCLK for latching the test mode activation signal TMCLK-EN is only an example and may be implemented with other internal clocks ICLK, QCLK, ICLKB depending on the embodiment.

The clock activation signal calibration circuit 15 is electrically connected to the code selection circuit 11 and the clock activation signal latch 13, receives the selected calibration code SCAL-CD form the code selection circuit 11, and receives the latch clock activation signal SCAL-EN from the clock activation signal latch 13. The clock activation signal calibration circuit 15 generates a delayed clock activation signal CLK-ENd based on the selected calibration code SCAL-CD and the latch clock activation signal SCAL-EN. The clock activation signal calibration circuit 15 delays the latch clock activation signal LCLK-EN by a calibration period set by the selected calibration code SCAL-CD to generate the delayed clock activation signal CLK-ENd.

The clock calibration circuit 17 is electrically connected to the code selection circuit 11 and the clock activation signal calibration circuit 15, receives the calibration code CAL-CD from the code selection circuit 11, and receives the delayed clock activation signal CLK-ENd from the clock activation signal calibration circuit 15. The clock calibration circuit 17 calibrates the internal clock signals ICLK, QCLK, ICLKB, and QCLKB to generate internal calibration clock signals ICLK-C, QCLK-C, ICLKB-C, and QCLKB-C, respectively, based on the selected calibration code SCAL-CD and the delayed clock activation signal CLK-ENd. The clock calibration circuit 17 generates the internal calibration clock signals ICLK-C, QCLK-C, ICLKB-C, and QCLKB-C by delaying the internal clock signals ICLK, QCLK, ICLKB, and QCLKB, respectively, by the calibration period set by the selected calibration code SCAL-CD after the delayed clock activation signal CLK-ENd is activated. The delayed clock activation signal CLK-ENd is a signal generated by delaying the latch clock activation signal LCLK-EN by the calibration period, so the delayed clock activation signal CLK-ENd is activated after the calibration code CAL-CD is updated. Accordingly, in an embodiment, the clock calibration circuit 17 generates the internal calibration clock signals ICLK-C, QCLK-C, ICLKB-C, and QCLKB-C by calibrating the internal clock signals ICLK, QCLK, ICLKB, and QCLKB, respectively, after the calibration code CAL-CD is updated by the delayed clock activation signal CLK-ENd, so that a glitch occurring in the internal clock signals ICLK, QCLK, ICLKB, and QCLKB according to the update of the calibration code CAL-CD can be prevented or mitigated from being included in the internal calibration clock signals ICLK-C, QCLK-C, ICLKB-C, and QCLKB-C.

FIG. 2 illustrates a calibration code generation circuit 10 according to an embodiment of the present disclosure, for example, as shown in FIG. 1.

As shown in FIG. 2, the calibration code generation circuit 10 includes a synthetic test strobe generation circuit (TSTB-S GEN) 101, a clock strobe generation circuit (CLK-STB GEN) 103, and a strobe comparison circuit (STB COM) 105.

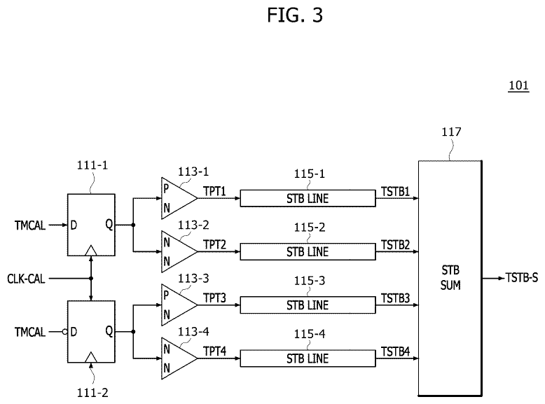

The synthetic test strobe generation circuit 101 generates a synthetic test strobe TSTB-S based on a calibration mode signal TMCAL and a calibration clock signal CLK-CAL. The synthetic test strobe generation circuit 101 latches the calibration test mode signal TMCAL to generate a plurality of test patterns, for example, TPT1, TPT2, TPT3, and TPT4 of FIG. 3 and synthesizes the plurality of test patterns to generate the synthetic test strobe TSTB-S based on the calibration clock signal CLK-CAL. The plurality of test patterns may be set to transition from a logic low level to a logic high level or from a logic high level to a logic low level, and may be driven by a plurality of drivers having different driving forces, for example, a PN driver and an NN driver in FIG. 3. The synthetic test strobe generation circuit 101 transmits each of the plurality of test patterns to a strobe line to generate a plurality of test strobes, and synthesizes the plurality of test strobes to generate the synthetic test strobe TSTB-S. The synthetic test strobe generation circuit 101 generates the synthetic test strobe TSTB-S having a logic level that transitions in synchronization with a latest point in time among the points in time at which the logic levels of the plurality of test strobes transition.

The clock strobe generation circuit 103 generates the clock strobe CLK-STB based on the calibration test mode signal TMCAL and the calibration clock signal CLS-CAL. The clock strobe generation circuit 103 delays the calibration clock signal CLK-CAL by a preset clock delay period when the calibration test mode signal TMCAL is activated to generate the delayed calibration clock (not shown) and generates the clock strobe CLK-STB in synchronization with the delayed calibration clock. The clock delay period may be determined by a clock driver (not shown) that drives the calibration clock signal CLK-CAL and a clock transmission line (not shown) through which the calibration clock signal CLK-CAL is transmitted. The clock strobe generation circuit 103 generates the clock strobe CLK-STB generated as a pulse in synchronization with a first rising edge of the delayed calibration clock signal when the calibration test mode signal TMCAL is activated. The clock strobe CLK-STB may be generated as a pulse having a preset pulse width from a point in time when the first rising edge of the delayed calibration clock signal is generated.

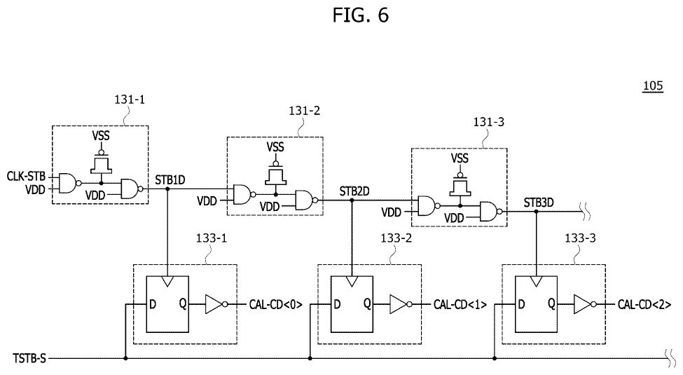

The strobe comparison circuit 105 is electrically connected to the synthetic test strobe generation circuit 101 and the clock strobe generation circuit 103 to receive the synthetic test strobe signal TSTB-S from the synthetic test strobe generation circuit 101 and receive the clock strobe CLK-STB from the clock strobe generation circuit 103. The strobe comparison circuit 105 generates the calibration code CAL-CD based on the synthetic test strobe signal TSTB-S and the clock strobe CLK-STB. The strobe comparison circuit 105 sequentially delays the clock strobe CLK-STB by a unit delay interval to generate a plurality of delayed strobes, for example, STB1D, STB2D, and STB3D in FIG. 6, and latches the synthetic test strobe TSTB-S in synchronization with each of the plurality of delayed strobes to generate the calibration code CAL-CD. The strobe comparison circuit 105 generates the calibration code CAL-CD including bits having a logic level that is determined according to a logic level of the synthetic test strobe TSTB-S latched in synchronization with each of the plurality of delayed strobes.

FIG. 3 illustrates a synthetic test strobe generation circuit 101 according to an embodiment of the present disclosure, for example, as shown in FIG. 2.

As shown in FIG. 3, the synthetic test strobe generation circuit 101 includes a first test input latch 111-1, a second test input latch 111-2, a first test driver 113-1, a second test driver 113-2, a third test driver 113-3, a fourth test driver 113-4, a first strobe line 115-1, a second strobe line 115-2, a third strobe line 115-3, a fourth strobe line 115-4, and a strobe synthesis circuit (STB SUM) 117.

The first test input latch 111-1 latches and outputs a calibration test mode signal TMCAL based on a calibration clock signal CLK-CAL. The first test input latch 111-1 latches and outputs the calibration test mode signal TMCAL in synchronization with a rising edge of the calibration clock signal CLK-CAL. The first test input latch 111-1 generates a signal that transitions from a logic low level to a logic high level at a time when the rising edge of the calibration clock signal CLK-CAL occurs.

The second test input latch 111-2 latches and outputs an inverted signal of the calibration test mode signal TMCAL based on the calibration clock signal CLK-CAL. The second test input latch 111-2 latches and outputs the inverted signal of the calibration test mode signal TMCAL in synchronization with the rising edge of the calibration clock signal CLK-CAL. The second test input latch 111-2 generates a signal having a logic level that transitions from a logic high level to a logic low level at a time when the rising edge of the calibration clock signal CLK-CAL occurs.

The first test driver 113-1 is electrically connected to the first test input latch 111-1 to receive a signal having a logic level that transitions from a logic low level to a logic high level at a time when the rising edge of the calibration clock CLK-CAL occurs. The first test driver 113-1 drives a first test pattern TPT1 based on an output signal of the first test input latch 111-1. The first test driver 113-1 may be implemented as a PN driver in which a PMOS transistor and an NMOS transistor are coupled in a CMOS structure. The PN driver pulls up the first test pattern TPT1 to a power supply voltage VDD by the PMOS transistor and drives the first test pattern TPT1 to a ground voltage VSS by the NMOS transistor. The PN driver drives the first test pattern TPT1 to the ground voltage VSS and then drives the first test pattern TPT1 to the power supply voltage VDD. In an embodiment, the P in PN driver stands for PMOS (P-type MOSFET) and the N stands for NMOS (N-type MOSFET). In an embodiment, the PN driver may be referred to as a push-pull driver or CMOS driver.

The second test driver 113-1 is electrically connected to the first test input latch 111-1 to receive a signal having a logic level that transitions from a logic low level to a logic high level at a time when the rising edge of the calibration clock signal CLK-CAL is generated. The second test driver 113-2 drives a second test pattern TPT2 based on an output signal of the first test input latch 111-1. The second test driver 113-2 may be implemented as an NN driver using only NMOS transistors. The NN driver pulls up the second test pattern TPT2 to the power supply voltage VDD threshold voltage Vth by the NMOS transistor, and drives the second test pattern TPT2 to the ground voltage VSS by the NMOS transistor. The NN driver drives the second test pattern TPT2 to the ground voltage VSS and then drives the second test pattern TPT2 to the power supply voltage VDD threshold voltage Vth. The NN driver consumes more power than the PN driver, but has greater driving power and can perform higher-speed operations than the PN driver. In an embodiment, the NN driver may be referred to as a pull-down driver or a low-side driver including NMOS transistors.

The third test driver 113-3 is electrically connected to the second test input latch 111-2 to receive a signal having a logic level that transitions from a logic high level to a logic low level at a time when the rising edge of the calibration clock CLK-CAL is generated. The third test driver 113-3 drives a third test pattern TPT3 based on an output signal of the second test input latch 111-2. The third test driver 113-3 may be implemented as a PN driver in which PMOS transistors and NMOS transistors are coupled in a CMOS structure. The PN driver pulls up the third test pattern TPT3 to the supply voltage VDD by the PMOS transistor and drives the third test pattern TPT3 to the ground voltage VSS by the NMOS transistor. The PN driver drives the third test pattern TPT3 to the ground voltage VSS and then drives the third test pattern TPT3 to the supply voltage VDD.

The fourth test driver 113-4 is electrically connected to the second test input latch 111-2 to receive a signal having a logic level that transitions from a logic high level to a logic low level at a point in time when the rising edge of the calibration clock signal CLK-CAL occurs from the second test input latch 111-2. The fourth test driver 113-4 drives a fourth test pattern TPT4 based on an output signal of the second test input latch 111-2. The fourth test driver 113-4 may be implemented as an NN driver using only NMOS transistors. The NN driver pulls up the fourth test pattern TPT4 to the power supply voltage VDD-the threshold voltage Vth by the NMOS transistor, and drives the fourth test pattern TPT4 to the ground voltage VSS by the NMOS transistor. The NN driver drives the fourth test pattern TPT4 to the ground voltage VSS and then drives the fourth test pattern TPT4 with the power supply voltage VDD-the threshold voltage Vth.

The first strobe line 115-1 is electrically connected between the first test driver 113-1 and the strobe synthesis circuit 117. The first test pattern TPT1 output from the first test driver 113-1 is transmitted through the first strobe line 115-1 and is received by the strobe synthesis circuit 117 as a first test strobe TSTB1. The first test strobe TSTB1 is generated by transmitting the first test pattern TPT1 driven by the first test driver 113-1 implemented as the PN driver through the first strobe line 115-1. Therefore, the point in time at which the first test strobe TSTB1 transitions from a logic low level to a logic high level may be determined by the driving force of the first test driver 113-1 and the transmission characteristics of the first strobe line 115-1.

The second strobe line 115-2 is electrically connected between the second test driver 113-2 and the strobe synthesis circuit 117. The second test pattern TPT2 output from the second test driver 113-2 is transmitted through the second strobe line 115-2 and received by the strobe synthesis circuit 117 as a second test strobe TSTB2. The second test strobe TSTB2 is generated by transmitting the second test pattern TPT2 driven by the second test driver 113-2 implemented as an NN driver through the second strobe line 115-2. Therefore, the point in time at which the logic level of the second test strobe TSTB2 transitions from a logic low level to a logic high level may be determined by the driving force of the second test driver 113-2 and the transmission characteristics of the second strobe line 115-2.

The third strobe line 115-3 is electrically connected between the third test driver 113-3 and the strobe synthesis circuit 117. The third test pattern TPT3 output from the third test driver 113-3 is transmitted through the third strobe line 115-3 and received by the strobe synthesis circuit 117 as a third test strobe TSTB3. The third test strobe TSTB3 is generated by transmitting the third test pattern TPT3 driven by the third test driver 113-3 implemented as a PN driver through the third strobe line 115-3. Therefore, the point in time at which the logic level of the third test strobe TSTB3 transitions from a logic low level to a logic high level may be determined by the driving force of the third test driver 113-3 and the transmission characteristics of the third strobe line 115-3.

The fourth strobe line 115-4 is electrically connected between the fourth test driver 113-4 and the strobe synthesis circuit 117. The fourth test pattern TPT4 output from the fourth test driver 113-4 is transmitted through the fourth strobe line 115-4 and received by the strobe synthesis circuit 117 as a fourth test strobe TSTB4. The fourth test strobe TSTB4 is generated by transmitting the fourth test pattern TPT4 driven by the fourth test driver 113-4 implemented as an NN driver through the fourth strobe line 115-4. Therefore, the point in time at which the logic level of the fourth test strobe TSTB4 transitions from a logic low level to a logic high level may be determined by the driving force of the fourth test driver 113-4 and the transmission characteristics of the fourth strobe line 115-4.

The strobe synthesis circuit 117 is electrically connected to the first strobe line 115-1, the second strobe line 115-2, the third strobe line 115-3, and the fourth strobe line 115-4 to receive the first test strobe TSTB1 from the first strobe line 115-1, receive the second test strobe TSTB2 from the second strobe line 115-2, receive the third test strobe TSTB3 from the third strobe line 115-3, and receive the fourth test strobe TSTB4 from the fourth strobe line 115-4. The strobe synthesis circuit 117 generates the synthetic test strobe TSTB-S based on the first test strobe TSTB1, the second test strobe TSTB2, the third test strobe TSTB3, and the fourth test strobe TSTB4. The strobe synthesis circuit 117 generates the synthetic test strobe TSTB-S having a logic level that transitions in synchronization with a latest logic level transition time among the logic level transition times of the first test strobe TSTB1, the second test strobe TSTB2, the third test strobe TSTB3, and the fourth test strobe TSTB4. For example, when the logic level of the first test strobe TSTB1 transitions from a logic low level to a logic high level at a first time point, the logic level of the second test strobe TSTB2 transitions from a logic low level to a logic high level at a second time point, the logic level of the third test strobe TSTB3 transitions from a logic high level to a logic low level at a third time point, and the logic level of the fourth test strobe TSTB4 transitions from a logic high level to a logic low level at a fourth time point, and the third time point is the latest among the first to fourth time points, the strobe synthesis circuit 117 generates the synthetic test strobe TSTB-S having a logic level that transitions from a logic low level to a logic high level in synchronization with the third point in time.

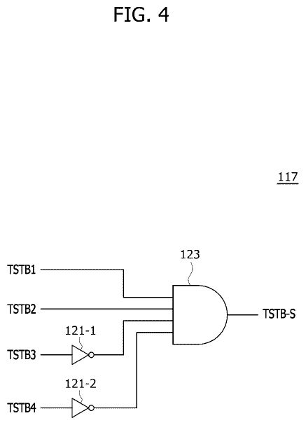

FIG. 4 illustrates a strobe synthesis circuit 117 according to an embodiment of the present disclosure, for example, as shown in FIG. 3.

As shown in FIG. 4, the strobe synthesis circuit 117 includes inverters 121-1 and 121-2 and an AND gate 123. The inverter 121-1 inversely buffers a third test strobe TSTB3 and outputs an inversely buffered third test strobe TSTB3, and the inverter 121-2 inversely buffers a fourth test strobe TSTB4 and outputs an inversely buffered fourth test strobe TSTB4. The AND gate 123 receives a first test strobe TSTB1, a second test strobe TSTB2, an output signal of the inverter 121-1, and an output signal of the inverter 121-2 and performs a logical AND operation. The strobe synthesis circuit 117 generates a synthetic test strobe TSTB-S having a logic level that transitions from a logic low level to a logic high level in synchronization with a latest logic level transition time among the logic level transition times of the first test strobe TSTB1, the second test strobe TSTB2, the third test strobe TSTB3, and the fourth test strobe TSTB4.

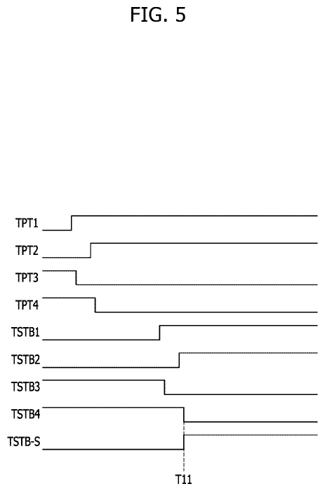

FIG. 5 is a timing diagram during an operation of a strobe synthesis circuit 117 according to an embodiment of the present disclosure, for example, as shown in FIG. 4.

As shown in FIG. 5, the logic levels of a first test pattern TPT1 driven by a first test driver 113-1 in FIG. 3 implemented as a PN driver, a second test pattern TPT2 driven by a second test driver 113-2 in FIG. 3 implemented as an NN driver, a third test pattern TPT3 driven by a third test driver 113-3 in FIG. 3 implemented as a PN driver, and a fourth test pattern TPT4 driven by a fourth test driver 113-4 in FIG. 3 implemented as an NN driver transition at different points in time. The logic levels of a first test strobe TSTB1 generated when the first test pattern TPT1 is transmitted through a first strobe line 115-1 in FIG. 3, a second test strobe TSTB2 generated when the second test pattern TPT2 is transmitted through a second strobe line 115-2 in FIG. 3, a third test strobe TSTB3 generated when the third test pattern TPT3 is transmitted through a third strobe line 115-3 in FIG. 3, and a fourth test strobe TSTB4 generated when the fourth test pattern TPT4 is transmitted through a fourth strobe line 115-4 in FIG. 3 transition at different points in time. The synthetic test strobe TSTB-S is generated in synchronization with a latest logic level transition time T11 among logic level transition times of the first test strobe TSTB1, the second test strobe TSTB2, the third test strobe TSTB3, and the fourth test strobe TSTB4, that is, the point in time at which the logic level of the fourth test strobe TSTB4 transitions from a logic high level to a logic low level. That is, all the logic level transitions times of the first test strobe TSTB1, the second test strobe TSTB2, the third test strobe TSTB3, occurs before the point in time at which the logic level of the fourth test strobe TSTB4 transitions from a logic high level to a logic low level. Thus, in this example, the synthetic test strobe TSTB-S is generated in synchronization with a latest logic level transition time T11 which is the logic level transition time for the fourth test strobe TSTB4. In another example, apart from what is shown in FIG. 5, when the third test strobe TSTB3 transitions at the latest time among the logic level transition times of the first test strobe TSTB1, the second test strobe TSTB2, and the fourth test strobe TSTB4, then the synthetic test strobe TSTB-S is generated in synchronization with the logic level transition time for the third test strobe TSTB3.

FIG. 6 illustrates a strobe comparison circuit 105 according to an embodiment of the present disclosure, for example, as shown in FIG. 2.

As shown in FIG. 6, the strobe comparison circuit 105 includes a first strobe delay circuit 131-1, a first calibration code latch circuit 133-1, a second strobe delay circuit 131-2, a second calibration code latch circuit 133-2, a third strobe delay circuit 131-3, and a third calibration code latch circuit 133-3.

The first strobe delay circuit 131-1 delays the clock strobe CLK-STB by a first unit delay interval based on a power supply voltage VDD to generate a first delayed strobe STB1D. The first strobe delay circuit 131-1 may be implemented as a resistance-capacitor (RC) delay circuit, but this is only an example and is not limited thereto. The capacitor included in the first strobe delay circuit 131-1 may be implemented as a MOS transistor that receives a ground voltage VSS through a gate.

The first calibration code latch circuit 133-1 is electrically connected to the first strobe delay circuit 131-1 and receives the first delayed strobe STB1D from the first strobe delay circuit 131-1. The first calibration code latch circuit 133-1 generates a first bit CAL-CD<0> of a calibration code based on the first delayed strobe STB1D and a synthetic test strobe TSTB-S. The first calibration code latch circuit 133-1 latches the synthetic test strobe TSTB-S in synchronization with a rising edge of the first delayed strobe STB1D and outputs the latched synthetic test strobe TSTB-S as the first bit CAL-CD<0> of the calibration code.

The second strobe delay circuit 131-2 delays the first delayed strobe STB1D by a second unit delay interval based on the power supply voltage VDD to generate a second delayed strobe STB2D. The second strobe delay circuit 131-2 may be implemented as an RC delay circuit, but this is only an example and is not limited thereto. The second unit delay interval may be set identically to the first unit delay interval, but this is only an example and is not limited thereto.

The second calibration code latch circuit 133-2 is electrically connected to the second strobe delay circuit 131-2 and receives the second delayed strobe STB2D from the second strobe delay circuit 131-2. The second calibration code latch circuit 133-2 generates a second bit CAL-CD<1> of the calibration code based on the second delayed strobe STB2D and the synthetic test strobe TSTB-S. The second calibration code latch circuit 133-2 latches the synthetic test strobe TSTB-S in synchronization with a rising edge of the second delayed strobe STB2D and outputs the latched synthetic test strobe TSTB-S as the second bit CAL-CD<1> of the calibration code.

The third strobe delay circuit 131-3 delays the second delayed strobe STB2D by a third unit delay interval based on the power supply voltage VDD to generate a third delayed strobe STB3D. The third strobe delay circuit 131-3 may be implemented as an RC delay circuit, but this is only an example and is not limited thereto. The third unit delay interval may be set identically to the first unit delay interval, but this is only an example and is not limited thereto.

The third calibration code latch circuit 133-3 is electrically connected to the third strobe delay circuit 131-3 and receives the third delayed strobe STB3D from the third strobe delay circuit 131-3. The third calibration code latch circuit 133-3 generates a third bit CAL-CD<2> of the calibration code based on the third delayed strobe STB3D and the synthetic test strobe TSTB-S. The third calibration code latch circuit 133-3 latches the synthetic test strobe TSTB-S in synchronization with a rising edge of the third delayed strobe STB3D and outputs the latched synthetic test strobe TSTB-S as the third bit CAL-CD<2> of the calibration code.

The strobe comparison circuit 105 latches the synthetic test strobe TSTB-S in synchronization with the first delayed strobe STB1D generated by delaying the clock strobe CLK-STB by the first unit delay period and inverts the latched synthetic test strobe TSTB-S to output the first bit CAL-CD<0> of the calibration code. The strobe comparison circuit 105 latches the synthetic test strobe TSTB-S in synchronization with the second delayed strobe STB2D generated by delaying the first delayed strobe STB1D by the second unit delay interval, and inverts the latched synthetic test strobe TSTB-S to output the second bit CAL-CD<1> of the calibration code. The strobe comparison circuit 105 latches the synthetic test strobe TSTB-S in synchronization with the third delayed strobe STB3D generated by delaying the second delayed strobe STB2D by the third unit delay interval, and inverts the latched synthetic test strobe TSTB-S to output the third bit CAL-CD<2> of the calibration code. FIG. 6 illustrates only the first to third strobe delay circuits 131-1, 131-2, and 131-3 and the first to third calibration code latch circuits 133-1, 133-2, and 133-3 that generate the first to third bits CAL-CD<0:2> of the calibration code, respectively, but the number of strobe delay circuits and the number of calibration code latch circuits may increase proportionally depending on the number of calibration codes.

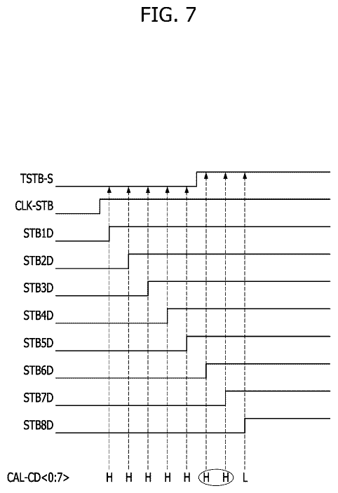

FIG. 7 is a timing diagram during an operation of a strobe comparison circuit 105 according to an embodiment of the present disclosure, for example, as shown in FIG. 6.

As shown in FIG. 7, the strobe comparison circuit 105 latches a synthetic test strobe TSTB-S in synchronization with a first delayed strobe STB1D generated by delaying a clock strobe CLK-STB by a first unit delay period, and inverts the latched synthetic test strobe TSTB-S to generate a first bit CAL-CD<0> of the calibration code of a logic high level (H).

As shown in FIG. 7, the strobe comparison circuit 105 latches the synthetic test strobe TSTB-S in synchronization with a second delayed strobe STB2D generated by delaying the first delayed strobe STB1D by a second unit delay period, and inverts the latched synthetic test strobe TSTB-S to generate a second bit CAL-CD<1> of the calibration code of a logic high level (H).

As shown in FIG. 7, the strobe comparison circuit 105 latches the synthetic test strobe TSTB-S in synchronization with a third delayed strobe STB3D generated by delaying the second delayed strobe STB2D by a third unit delay period, and inverts the latched synthetic test strobe TSTB-S to generate a third bit CAL-CD<2> of the calibration code of a logic high level (H).

As shown in FIG. 7, the strobe comparison circuit 105 latches the synthetic test strobe TSTB-S in synchronization with a fourth delayed strobe STB4D generated by delaying the third delayed strobe STB3D by a fourth unit delay period, and inverts the latched synthetic test strobe TSTB-S to generate a fourth bit CAL-CD<3> of the calibration code of the logic high level (H).

As shown in FIG. 7, the strobe comparison circuit 105 latches the synthetic test strobe TSTB-S in synchronization with a fifth delayed strobe STB5D generated by delaying the fourth delayed strobe STB4D by a fifth unit delay period, and inverts the latched synthetic test strobe TSTB-S to generate a fifth bit CAL-CD<4> of the calibration code of the logic high level (H).

As shown in FIG. 7, the strobe comparison circuit 105 latches the synthetic test strobe TSTB-S in synchronization with a sixth delayed strobe STB6D generated by delaying the fifth delayed strobe STB5D by a sixth unit delay period, and outputs the latched synthetic test strobe TSTB-S as a sixth bit CAL-CD<5> of the calibration code of the logic high level (H).

As shown in FIG. 7, the strobe comparison circuit 105 latches the synthetic test strobe TSTB-S in synchronization with a seventh delayed strobe STB7D generated by delaying the sixth delayed strobe STB6D by a seventh unit delay period, and outputs the latched synthetic test strobe TSTB-S as a seventh bit CAL-CD<6> of the calibration code of the logic high level (H).

The sixth and seventh bits CAL-CD<5:6> of the calibration code are not generated by inverting the latched synthetic test strobe TSTB-S unlike the first to fifth bits CAL-CD<0:4> of the calibration code. This is to increase the interval in which the sixth and seventh bits CAL-CD<5:6> of the calibration code are generated at a logic high level by the sixth and seventh unit delay intervals from a point in time when a logic level of the synthetic test strobe TSTB-S transitions from a logic low level to a logic high level, thereby enabling signals such as data, command, and address to be stably strobed by the synthetic test strobe TSTB-S.

As shown in FIG. 7, the strobe comparison circuit 105 latches the synthetic test strobe TSTB-S in synchronization with an eighth delayed strobe STB8D generated by delaying the seventh delayed strobe STB7D by an eighth delay interval, and inverts the latched synthetic test strobe TSTB-S to generate an eighth bit CAL-CD<7> of the calibration code of a logic low level (L).

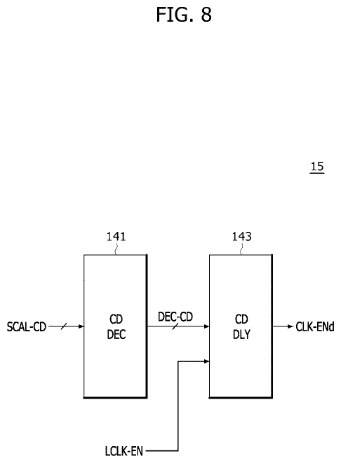

FIG. 8 illustrates a clock activation signal calibration circuit 15 according to an example of the present disclosure, for example, as shown in FIG. 1.

As shown in FIG. 8, the clock activation signal calibration circuit 15 includes a code decoder (CD DEC) 141 and a code delay circuit (CD DLY) 143.

The code decoder 141 decodes a selected calibration code SCAL-CD to generate a decoding code DEC-CD. The selected calibration code SCAL-CD includes a plurality of bits, and at least one of the bits included in the selected calibration code SCAL-CD may be activated to set a calibration delay interval. For example, among first to eighth bits SCAL-CD<0:7> of the selective calibration code, the first bit SCAL-CD<0> of the selective calibration code may be activated to set the calibration delay interval as a first delay interval. As another example, among the first to eighth bits SCAL-CD<0:7> of the selective calibration code, the first and second bits SCAL-CD<0:1> of the selective calibration code may be activated to set the calibration delay interval as a second delay interval. The decoding code DEC-CD includes a plurality of bits, and each bit included in the decoding code DEC-CD may be activated corresponding to a plurality of delay intervals. For example, among the first to eighth bits DEC-CD<0:7> of the decoding code, the first bit DEC-CD<0> of the decoding code may be activated to set the calibration delay interval as the first delay interval. As another example, among the first to eighth bits DEC-CD<0:7> of the decoding code, the second bit DEC-CD<1> of the decoding code may be activated to set the calibration delay interval as the second delay interval.

The code delay circuit 143 is electrically connected to the code decoder 141 to receive the decoding code DEC-CD from the code decoder 141. The code delay circuit 143 delays a latch clock activation signal LCLK-EN, based on the decoding code DEC-CD to generate a delayed clock activation signal CLK-End. The code delay circuit 143 delays the latch clock activation signal LCLK-EN by the delay interval set by the decoding code DEC-CD to generate the delayed clock activation signal CLK-ENd. For example, the code delay circuit 143 may generate the delayed clock activation signal CLK-ENd by delaying the latch clock activation signal LCLK-EN by the calibration delay period set as the second delay period when only the second bit DEC-CD<1> of the decoding code is activated among the first to eighth bits DEC-CD<0:7> of the decoding code.

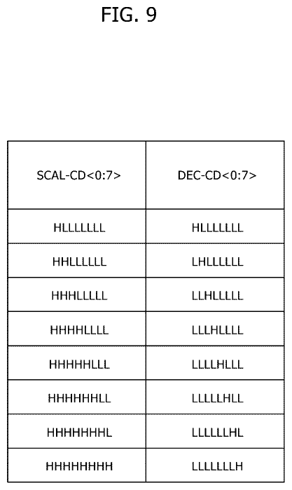

FIG. 9 is a table illustrating an operation of a code decoder 141 according to an embodiment of the present disclosure, for example, as shown in FIG. 8.

As shown in a first row in FIG. 9, the code decoder 141 converts first to eighth bits SCAL-CD<0:7> of a selective calibration code corresponding to a first delay interval to generate first to eighth bits DEC-CD<0:7> of a decoding code corresponding to the first delay interval. More specifically, when the first to eighth bits SCAL-CD<0:7> of the selection calibration code are received, in which only the first bit SCAL-CD<0> is activated at a logic high level “H”, the code decoder 141 generates the first to eighth bits DEC-CD<0:7> of the decoding code in which only the first bit DEC-CD<0> is activated at a logic high level “H”.

As shown in a second row in FIG. 9, the code decoder 141 converts the first to eighth bits SCAL-CD<0:7> of the selection calibration code corresponding to a second delay interval to generate the first to eighth bits DEC-CD<0:7> of the decoding code corresponding to the second delay interval. More specifically, when the first to eighth bits SCAL-CD<0:7> of the selection calibration code are received, in which both the first and second bits SCAL-CD<0:1> are activated at a logic high level “H”, the code decoder 141 generates the first to eighth bits DEC-CD<0:7> of the decoding code in which only the second bit DEC-CD<1> is activated at a logic high level “H”.

As shown in a third row in FIG. 9, the code decoder 141 converts the first to eighth bits SCAL-CD<0:7> of the selection calibration code corresponding to a third delay interval to generate the first to eighth bits DEC-CD<0:7> of the decoding code corresponding to the third delay interval. More specifically, when the first to eighth bits SCAL-CD<0:7> of the selection calibration code are received, in which the first to third bits SCAL-CD<0:2> are activated at a logic high level “H”, the code decoder 141 generates the first to eighth bits DEC-CD<0:7> of the decoding code in which only the third bit DEC-CD<2> is activated at a logic high level “H”.

As shown in a fourth row in FIG. 9, the code decoder 141 converts the first to eighth bits SCAL-CD<0:7> of the selection calibration code corresponding to a fourth delay interval to generate the first to eighth bits DEC-CD<0:7> of the decoding code corresponding to the fourth delay interval. More specifically, when the first to eighth bits SCAL-CD<0:7> of the selection calibration code are received, in which the first to fourth bits SCAL-CD<0:3> are activated at a logic high level “H”, the code decoder 141 generates the first to eighth bits DEC-CD<0:7> of the decoding code in which only the fourth bit DEC-CD<3> is activated at a logic high level “H”.

As shown in a fifth row in FIG. 9, the code decoder 141 converts the first to eighth bits SCAL-CD<0:7> of the selection calibration code corresponding to a fifth delay interval to generate the first to eighth bits DEC-CD<0:7> of the decoding code corresponding to the fifth delay interval. More specifically, when the first to eighth bits SCAL-CD<0:7> of the selection calibration code are received, in which the first to fifth bits SCAL-CD<0:4> are activated at a logic high level “H”, the code decoder 141 generates the first to eighth bits DEC-CD<0:7> of the decoding code in which only the fifth bit DEC-CD<4> is activated at a logic high level “H”.

As shown in a sixth row in FIG. 9, the code decoder 141 converts the first to eighth bits SCAL-CD<0:7> of the selection calibration code corresponding to a sixth delay interval to generate the first to eighth bits DEC-CD<0:7> of the decoding code corresponding to the sixth delay interval. More specifically, when the first to eighth bits SCAL-CD<0:7> of the selection calibration code are received, in which the first to sixth bits SCAL-CD<0:5> are activated at a logic high level “H”, the code decoder 141 generates the first to eighth bits DEC-CD<0:7> of the decoding code in which only the sixth bit DEC-CD<5> is activated at a logic high level “H”.

As shown in a seventh row in FIG. 9, the code decoder 141 converts the first to eighth bits SCAL-CD<0:7> of the selection calibration code corresponding to a seventh delay interval to generate the first to eighth bits DEC-CD<0:7> of the decoding code corresponding to the seventh delay interval. More specifically, when the first to eighth bits SCAL-CD<0:7> of the selection calibration code are received, in which the first to seventh bits SCAL-CD<0:6> are activated at a logic high level “H”, the code decoder 141 generates the first to eighth bits DEC-CD<0:7> of the decoding code in which only the seventh bit DEC-CD<6> is activated at a logic high level “H”.

As shown in an eighth row in FIG. 9, the code decoder 141 converts the first to eighth bits SCAL-CD<0:7> of the selection calibration code corresponding to an eighth delay interval to generate the first to eighth bits DEC-CD<0:7> of the decoding code corresponding to the eighth delay interval. More specifically, when the first to eighth bits SCAL-CD<0:7> of the selection calibration code are received, in which all of the first to eighth bits SCAL-CD<0:7> are activated at a logic high level “H”, the code decoder 141 generates the first to eighth bits DEC-CD<0:7> of the decoding code in which only the eighth bit DEC-CD<7> is activated at a logic high level “H”.

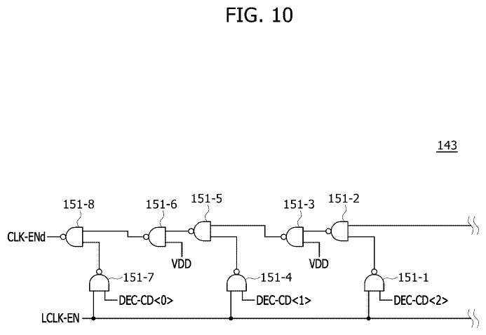

FIG. 10 illustrates a code delay circuit 143 according to an embodiment of the present disclosure, for example, as shown in FIG. 8.

As shown in FIG. 10, the code delay circuit 143 includes NAND gates 151-1, 151-2, 151-3, 151-4, 151-5, 151-6, 151-7, and 151-8. When only a first bit DEC-CD<0> of a decoding code is activated at a logic high level, the code delay circuit 143 delays a latch clock activation signal LCLK-EN by a calibration delay period set as a first delay period through the NAND gates 151-7 and 151-8 to generate a delayed clock activation signal CLK-ENd. When only a second bit DEC-CD<1> of the decoding code is activated at a logic high level, the code delay circuit 143 delays the latch clock activation signal LCLK-EN by the calibration delay period set as a second delay period through the NAND gates 151-4, 151-5, 151-6, and 151-8 to generate the delayed clock activation signal CLK-ENd. When only a third bit DEC-CD<2> of the decoding code is activated at a logic high level, the code delay circuit 143 delays the latch clock activation signal LCLK-EN by the calibration delay period set as a third delay period through the NAND gates 151-1, 151-2, 151-3, 151-5, 151-6, and 151-8 to generate the delayed clock activation signal CLK-ENd.

In FIG. 10, only the NAND gates 151-1, 151-2, 151-3, 151-4, 151-5, 151-6, 151-7, and 151-8 are disclosed for delaying the latch clock activation signal LCLK-EN by one of the first to third delay periods by the first to third bits DEC-CD<0:2> of the decoding code, but as the number of bits of the decoding code increases, the NAND gates may be added so that the delay period for delaying the latch clock activation signal LCLK-EN increases.

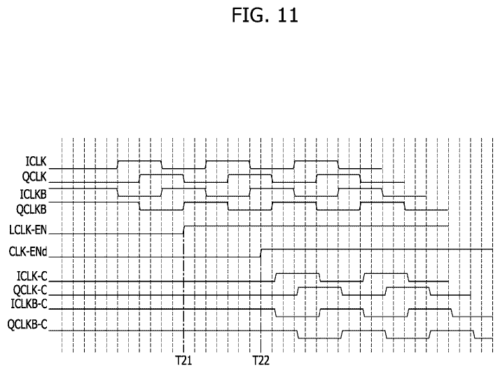

FIG. 11 is a timing diagram during operations of a clock activation signal calibration circuit 15 and a clock calibration circuit 17 according to an embodiment of the present disclosure, for example, as shown in FIG. 1.

As shown in FIG. 11, the clock activation signal calibration circuit 15 delays a latch clock activation signal LCLK-EN activated at a time T21 to generate a delayed clock activation signal CLK-ENd activated at a time T22, based on a selected calibration code SCAL-CD. Here, in an embodiment, the clock activation signal calibration circuit 15 decodes the selected calibration code SCAL-CD to generate a decoding code DEC_CD, and delays the latch clock activation signal LCLK-EN by the set calibration period (the period from time T21 to time T22) based on the decoding code DEC_CD to generate the delayed clock activation signal CLK-ENd, thereby preventing or mitigating a glitch from occurring in the delayed clock activation signal CLK-ENd when the selected calibration code SCAL-CD is updated.

As shown in FIG. 11, the clock calibration circuit 17 delays internal clock signals ICLK, QCLK, ICLKB, and QCLKB by the calibration period set by the selected calibration code SCAL-CD to generate internal calibration clock signals ICLK-C, QCLK-C, ICLKB-C, and QCLKB-C after the delayed clock activation signal CLK-ENd is activated at the time T21. Because the delayed clock activation signal CLK-ENd is a signal generated by delaying the latch clock activation signal LCLK-EN by the calibration period, the delayed clock activation signal CLK-ENd is activated after the calibration code CAL-CD is updated. Accordingly, in an embodiment, the clock calibration circuit 17 generates the internal calibration clock signals ICLK-C, QCLK-C, ICLKB-C, and QCLKB-C by calibrating the internal clock signals ICLK, QCLK, ICLKB, and QCLKB after the calibration code CAL-CD is updated by the delayed clock activation signal CLK-ENd, so that a glitch occurring in the internal clock signals ICLK, QCLK, ICLKB, and QCLKB according to the update of the calibration code CAL-CD can be prevented or mitigated from being included in the internal calibration clock signals ICLK-C, QCLK-C, ICLKB-C, and QCLKB-C. The internal calibration clock signals ICLK-C, QCLK-C, ICLKB-C, and QCLKB-C are sequentially generated after the delayed clock activation signal CLK-ENd is activated, and may be sequentially generated from various points in time depending on the embodiment.

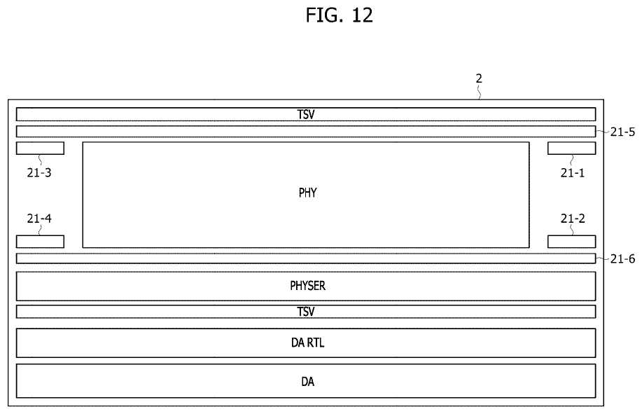

FIG. 12 illustrates a base die 2 according to an embodiment of the present disclosure.

As shown in FIG. 12, the base die 2 includes a physical layer (PHY), a serial-to-parallel conversion circuit (PHYSER), alignment circuits 21-1, 21-2, 21-3, 21-4, 21-5, and 21-6, through via regions (TSV), a direct access region (DA), and a logic circuit region (DA RTL).

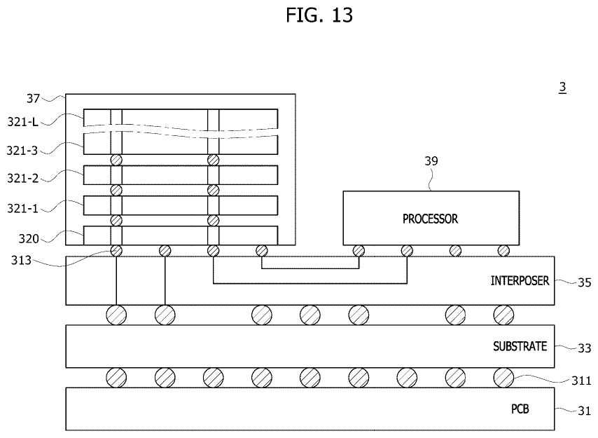

The physical layer (PHY) controls transmission of data, commands, and addresses between core dies and a processor, for example, a processor 49 in FIG. 13 through a plurality of channels. The physical layer (PHY) includes data control circuits that control the transmission of data through the plurality of channels and command address control circuits that control the transmission of commands and addresses through the plurality of channels. The physical layer (PHY) is used for high-speed data transmission, maintaining signal integrity, and low-power design in high bandwidth memory (HBM) systems.

The serial-to-parallel conversion circuit (PHYSER) converts serial signals transmitted serially through the physical layer (PHY) into parallel signals, aligns the converted parallel signals through the alignment circuits 21-1, 21-2, 21-3, 21-4, 21-5, and 21-6, and then transmits the converted and aligned parallel signals to the through via regions (TSV). The internal clock generation circuit 1 shown in FIG. 1 may be disposed in the alignment circuits 21-1, 21-2, 21-3, 21-4, 21-5, and 21-6. According to an embodiment, the internal clock generation circuit 1 may be disposed in some of the alignment circuits 21-1, 21-2, 21-3, 21-4, 21-5, and 21-6, and the selected calibration code SCAL-CD generated in the internal clock generation circuit 1 may be transmitted to the remaining alignment circuits 21-1, 21-2, 21-3, 21-4, 21-5, and 21-6. The alignment circuits 21-1, 21-2, 21-3, and 21-4 may be implemented as circuits that align data and the alignment circuits 21-5 and 21-6 may be implemented as circuits that align commands, addresses, and data, but this is only an example and the present disclosure is not limited thereto. The positions and numbers of the alignment circuits 21-1, 21-2, 21-3, 21-4, 21-5, and 21-6 may be variously modified according to the embodiment.

The through via region (TSV) includes a plurality of through vias that connect the base die 2 and a plurality of core dies, and transmits parallel signals transmitted from the serial-to-parallel conversion circuit (PHYSER) to the core dies or output the parallel signals transmitted from the core dies to the serial-to-parallel conversion circuit (PHYSER).

The direct access region (DA) includes pads used to directly access the core dies without going through a memory controller, etc. in a processor, for example, a processor 39 in FIG. 13. Signals used for performing various tests, such as tests based on the IEEE 1500 standard, may be transmitted through the direct access region (DA). In an embodiment, the direct access region (DA) can provide low latency and high bandwidth, and can reduce power consumption.

The logic circuit region (DA RTL) is implemented as a register transfer level (RTL) circuit and can control or test the operation of core dies, for example, core die 321-1 to core die 321-L in FIG. 13, stacked over the base die 2.

FIG. 13 illustrates a memory system 3 according to an embodiment of the present disclosure.

As shown in FIG. 13, the memory system 3 includes a printed circuit board (PCB) 31, a substrate 33, an interposer 35, a memory device 37, and a processor 39.

The printed circuit board 31 connects various electronic components to each other to form electronic circuits. The electronic circuits include the memory system 3. A copper (Cu) layer, a solder mask, a silk screen, and so forth are formed on the printed circuit board 31. Circuit paths that transmit or transfer signals or power are formed in the copper (Cu) layer. In an embodiment, the solder mask prevents or mitigates damage to the circuits and protects a specific region where components are soldered. The silk screen indicates location or information for the electronic components as characters or symbols printed on a surface of the printed circuit board 31.

The substrate 33 is disposed over the printed circuit board 31 with bump pads in between, for example, bump pads 311 and mechanically supports the interposer 35, the memory device 37, and the processor 39. The substrate 33 functions as a physical base for the printed circuit board 31 and is an insulator. The substrate 33 may include materials such as flame retardant four (FR4) that is an insulator made of fiberglass and epoxy resin, ceramics that can withstand high temperatures, have appropriate thermal conductivity properties, and are used in high-frequency circuits, polyimide that is used as a basic material for flexible PCBs due to flexible characteristics, and the like.

The interposer 35 is disposed over the substrate 33 with bump pads in between and includes wiring that connects electronic components, for example, the memory device 37 and the processor 39, that have form factors or pin arrangements do not match or have different spacing. The interposer 35 converts signals from different interfaces, such as double data rate (DDR), high bandwidth memory (HBM), peripheral component interconnect express (PCIe).

The memory device 37 is disposed over the interposer 35 with pads in between, for example, micro bump pads 313. The memory device 37 stores data received from the processor 39 or outputs the stored data to the processor 39 under control of the processor 39. The memory device 37 includes a base die 320 and a plurality of core dies 321-1 to 321-L, where L is an integer greater than 1. The core dies 321-1 to 321-L are stacked over the base die 320 with micro bump pads in between. The base die 320 and the core dies 321-1 to 321-L are vertically connected to each other using through vias and micro bump pads. The base die 320 controls data transmission between the processor 39 and the core dies 321-1 to 321-L. The base die 320 receives input/output power voltage (voltage drain drain for IO also referred to as output stage drain power voltage) VDDQ as an operating voltage utilized during operation of internal circuits included in the base die 320. The base die 320 receives the input/output power voltage VDDQ from the printed circuit board 31 through the substrate 33 and the interposer 35. The input/output power voltage VDDQ is a voltage supplied to buffers that transmit data and is distinguished or different from the power supply voltage VDD. The core dies 321-1 to 321-L use a peripheral voltage VPERI as an operating voltage during operation of the internal circuits included in the core dies 321-1 to 321-L. The core dies 321-1 to 321-L generate the peripheral voltage VPERI from the input/output power voltage VDDQ received through the base die 320. The core dies 321-1 to 321-L generate the peripheral voltage VPERI at a lower voltage level than the input/output power voltage VDDQ and use the peripheral voltage VPERI as an operating voltage. Each of the core dies 321-1 to 321-L includes a plurality of channel regions, for example, eight channel regions or sixteen channel regions that operate independently. Each of the plurality of channel regions is allocated with a channel operating independently to receive or transmit data. The number L of core dies 321-1 to 321-L may be four, eight, twelve, sixteen, and so forth. For example, when each of the core dies 321-1 to 321-12 has eight channels, the core dies 321-1 to 321-4, the core dies 321-5 to 321-8, and the core dies 321-9 to 321-12 each include thirty-two channel regions, and transmit and receive data with the processor 39 in units of a rank including thirty-two channels.

In an embodiment, the base die 320 may be implemented as the base die 2 shown in FIG. 12, and the base die 320 may include the internal clock generation circuit 1 shown in FIG. 1, which delays a clock activation signal based on a calibration code used for calibrating an internal clock signal to generate a delayed clock activation signal, and calibrates the internal clock signal according to the calibration code after the delayed clock activation signal is activated, thereby preventing or mitigating a glitch from occurring in the calibrated internal clock signal.

Concepts are disclosed in conjunction with various examples and embodiments. Those skilled in the art will understand that various modifications, additions, and substitutions are possible without departing from the scope and technical concepts of the present disclosure. The embodiments disclosed in the present specification should be considered from an illustrative standpoint and not a restrictive standpoint. The scope of the present disclosure is not limited to the descriptions. All changes within the meaning and range of equivalency of the claims are included within their scope.

What is claimed is:

1. A memory device comprising:
a calibration code generation circuit configured to generate a calibration code based on a calibration test mode signal and a calibration clock signal;
a code selection circuit configured to select one of the calibration code and a manual code as a selected calibration code based on a manual test mode signal;
a clock activation signal calibration circuit configured to delay a latch clock activation signal based on the selected calibration code to generate a delayed clock activation signal; and
a clock calibration circuit configured to calibrate internal clock signals based on the selected calibration code and the delayed clock activation signal to generate internal calibration clock signals.

2. The memory device of claim 1, wherein the calibration code generation circuit receives the calibration test mode signal that is a test mode signal activated for a calibration test operation.

3. The memory device of claim 1, wherein the calibration code generation circuit is configured to:
generate a synthetic test strobe and a clock strobe based on the calibration test mode signal and the calibration clock signal, and
compare the synthetic test strobe and the clock strobe to generate the calibration code.

4. The memory device of claim 1, wherein the calibration code generation circuit comprises:
a synthetic test strobe generation circuit configured to generate a synthetic test strobe based on the calibration test mode signal and the calibration clock signal;
a clock strobe generation circuit configured to generate a clock strobe based on the calibration test mode signal and the calibration clock signal; and
a strobe comparison circuit configured to compare the synthetic test strobe and the clock strobe to generate the calibration code.

5. The memory device of claim 4, wherein the synthetic test strobe generation circuit is configured to:
latch the calibration test mode signal based on the calibration clock signal to generate a plurality of test patterns, and
synthesize the plurality of test patterns to generate the synthetic test strobe.

6. The memory device of claim 5,
wherein the synthetic test strobe generation circuit generates first to fourth test patterns,
wherein a logic level of the first test pattern transitions from a logic low level to a logic high level and the first test pattern is driven by a PMOS and NMOS (PN) driver,
wherein a logic level of the second test pattern transitions from a logic low level to a logic high level and the second test pattern is driven by an NMOS and NMOS (NN) driver,
wherein a logic level of the third test pattern transitions from a logic high level to a logic low level and the third test pattern is driven by a PN driver, and
wherein a logic level of the fourth test pattern transitions from a logic high level to a logic low level and the fourth test pattern is driven by an NN driver.

7. The memory device of claim 4, wherein the synthetic test strobe generation circuit comprises:
a first test input latch configured to latch and output the calibration test mode signal based on the calibration clock signal;
a second test input latch configured to latch and output an inverted signal of the calibration test mode signal based on the calibration clock signal;
a first test driver implemented as a PN driver and configured to drive the first test pattern based on an output signal of the first test input latch;
a second test driver implemented as an NN driver and configured to drive the second test pattern based on the output signal of the first test input latch;
a third test driver implemented as a PN driver and configured to drive the third test pattern based on an output signal of the second test input latch; and
a fourth test driver implemented as an NN driver and configured to drive the fourth test pattern based on the output signal of the second test input latch.

8. The memory device of claim 7, wherein the synthetic test strobe generation circuit further comprises:
a first strobe line that transmits the first test pattern as a first test strobe;
a second strobe line that transmits the second test pattern as a second test strobe;
a third strobe line that transmits the third test pattern as a third test strobe;
a fourth strobe line that transmits the fourth test pattern as a fourth test strobe; and
a strobe synthesis circuit that generates the synthesis test strobe based on the first test strobe, the second test strobe, the third test strobe, and the fourth test strobe.

9. The memory device of claim 8, wherein the strobe synthesis circuit generates the synthetic test strobe comprising a logic level that transitions in synchronization with a latest logic level transition time among logic level transition times of the first test strobe, the second test strobe, the third test strobe, and the fourth test strobe.

10. The memory device of claim 4, wherein the clock strobe generation circuit is configured to:
delay the calibration clock signal by a preset clock delay period to generate a delayed calibration clock signal when the calibration test mode signal is activated; and
generate the clock strobe in synchronization with the delayed calibration clock signal.

11. The memory device of claim 4, wherein the strobe comparison circuit is configured to:
delay the clock strobe sequentially by a unit delay period to generate a plurality of delayed strobes; and
latch the synthesis test strobe in synchronization with each of the plurality of delayed strobes to generate the calibration code.

12. The memory device of claim 4, wherein the strobe comparison circuit comprises:
a first strobe delay circuit configured to delay the clock strobe by a first unit delay period to generate a first delayed strobe;
a first calibration code latch circuit configured to latch the synthetic test strobe based on the first delayed strobe signal to output the synthetic test strobe as a first bit of the calibration code;
a second strobe delay circuit configured to delay the first delayed strobe by a second unit delay period to generate a second delayed strobe; and
a second calibration code latch circuit configured to latch the synthetic test strobe based on the second delayed strobe signal to output the synthetic test strobe as a second bit of the calibration code.

13. The memory device of claim 12, wherein the strobe comparison circuit sets the first unit delay period and the second unit delay period to be substantially the same.

14. The memory device of claim 1, wherein the clock activation signal calibration circuit comprises:
a code decoder configured to decode the selected calibration code to generate a decoding code; and
a code delay circuit configured to delay the latch clock activation signal based on the decoding code to generate the delayed clock activation signal.

15. The memory device of claim 14, wherein the code decoder generates the decoding code including bits in a binary bit set that is set differently from a binary bit set of bits included in the selected calibration code.

16. The memory device of claim 14, wherein the code delay circuit is configured to:
delay the latch clock activation signal by a first delay period to generate the delayed clock activation signal when a first bit of the decoding code is activated, and
delay the latch clock activation signal by a second delay period to generate the delayed clock activation signal when a second bit of the decoding code is activated.

17. The memory device of claim 1, wherein the clock calibration circuit delays the internal clock signals by a calibration delay period set by the selected calibration code to generate the internal calibration clock signals after the delayed clock activation signal is activated.

18. A memory system comprising:
a base die and a plurality of core dies disposed over an interposer,
wherein the base die comprises:
a calibration code generation circuit configured to generate a calibration code based on a calibration test mode signal and a calibration clock signal;
a code selection circuit configured to select one of the calibration code and a manual code as a selected calibration code based on a manual test mode signal;
a clock activation signal calibration circuit configured to delay a latch clock activation signal based on the selected calibration code to generate a delayed clock activation signal; and
a clock calibration circuit configured to calibrate internal clock signals based on the selected calibration code and the delayed clock activation signal to generate internal calibration clock signals.

19. The memory system of claim 18, wherein the calibration code generation circuit is configured to:
generate a synthetic test strobe and a clock strobe based on the calibration test mode signal and the calibration clock, and
compare the synthetic test strobe and the clock strobe to generate the calibration code.

20. The memory system of claim 18, wherein the calibration code generation circuit comprises:
a synthetic test strobe generation circuit configured to generate a synthetic test strobe based on the calibration test mode signal and the calibration clock signal;
a clock strobe generation circuit configured to generate a clock strobe based on the calibration test mode signal and the calibration clock signal; and
a strobe comparison circuit configured to compare the synthetic test strobe and the clock strobe to generate the calibration code.

21. The memory system of claim 18, wherein the clock activation signal calibration circuit comprises:
a code decoder configured to decode the selected calibration code to generate a decoding code; and
a code delay circuit configured to delay the latch clock activation signal based on the decoding code to generate the delayed clock activation signal.

22. The memory system of claim 21, wherein the code decoder generates the decoding code including bits in a binary bit set that are set differently from a binary bit set of bits included in the selected calibration code.

23. The memory system of claim 21, wherein the code delay circuit is configured to:
delay the latch clock activation signal by a first delay period to generate the delayed clock activation signal when a first bit of the decoding code is activated, and
delay the latch clock activation signal by a second delay period to generate the delayed clock activation signal when a second bit of the decoding code is activated.

24. The memory system of claim 18, wherein the clock calibration circuit delays the internal clock signals by a calibration delay period set by the selected calibration code to generate the internal calibration clock signals after the delayed clock activation signal is activated.

25. A memory system comprising:
a base die configured to control a plurality of core dies,
wherein the base die comprises:
a physical layer configured to control transmission of data, commands, and addresses using a plurality of channels between the core dies and a processor; and
a serial-to-parallel conversion circuit configured to convert serial signals transmitted serially through the physical layer into parallel signals, align the converted parallel signals through a plurality of alignment circuits, and transmit the parallel signals to a through via region,
wherein at least one of the plurality of alignment circuits comprises an internal clock generation circuit configured to generate a calibration code based on a calibration test mode signal and a calibration clock signal, delays a latch clock activation signal based on the calibration code to generate a delayed clock activation signal, and calibrates internal clock signals based on the calibration code to generate internal calibration clock signals.

26. The memory system of claim 25, wherein the calibration code generated from the least one of the plurality of alignment circuits is transmitted to the remaining of the plurality of alignment circuits.

27. The memory system of claim 25, wherein the internal clock generation circuit comprises:
a calibration code generation circuit configured to generate the calibration code based on a calibration test mode signal and a calibration clock signal;
a clock activation signal calibration circuit configured to delay a latch clock activation signal based on the calibration code to generate a delayed clock activation signal; and
a clock calibration circuit configured to calibrate the internal clock signals based on the calibration code and the delayed clock activation signal to generate the internal calibration clock signals.

28. The memory system of claim 27, wherein the calibration code generation circuit is configured to:
generate a synthetic test strobe and a clock strobe based on the calibration test mode signal and the calibration clock signal, and
compare the synthetic test strobe and the clock strobe to generate the calibration code.
